(19) United States
(12) Patent Application Publication
(10) Pub. No.: US 2023/0299762 A1
(43) Pub. Date: Sep. 21, 2023

(54) LEVEL SHIFTER AND ELECTRONIC DEVICE

(71) Applicant: FARADAY TECHNOLOGY CORPORATION, Hsinchu (TW)

(72) Inventors: Hussainvali SHAIK, Hsinchu (TW); Sridhar CHERUKU, Hsinchu (TW); Sivaramakrishnan SUBRAMANIAN, Hsinchu (TW)

(21) Appl. No.: 17/694,727

(22) Filed: Mar. 15, 2022

(51) Int. Cl. H03K 17/081; H03K 17/041

(52) U.S. Cl. CPC H03K 17/08104; H03K 17/04106

(57) ABSTRACT

A level shifter and an electronic device are provided. The electronic device includes a digital circuit and a level shifter. The level shifter converts a first and a second input signals to an output signal. The level shifter includes a cross-coupled circuit, a protection circuit, and a pull-down module. The cross-coupled circuit includes a first and a second pull-up transistors. The protection circuit includes a first and a second protection transistors. The pull-down module includes a first and a second pull-down circuits and a first and a second switching circuits. The first and the second pull-up transistors, the first and the second protection transistors, and the first and the second pull-down circuits are selectively switched on in response to the first and the second input signals. The digital circuit receives the output signal from the level shifter.

### TECHNICAL FIELD

The disclosure relates in general to a level shifter and an electronic device, and more particularly to a level shifter and an electronic device suitable for high-speed applications.

### BACKGROUND

Level shifter transforms an input signal IN having a first voltage value to an output signal OUT having a second voltage value. As the level shifter improves the compatibility between integrated circuits with different voltage requirements, the level shifter is widely used in electronic devices such as memory devices, memory controllers, high-speed input/output (I/O) circuits, and so forth. With the speed/frequency increment of electronic devices, the precision of the output signal OUT generated by the level shifter should be concerned.

### SUMMARY

The disclosure is directed to a level shifter and an electronic device. The electronic device includes a digital circuit and the level shifter, and the digital circuit receives an output signal from the level shifter. In response to a rising transition of an input signal, a pull-down current of the level shifter can be cut off immediately. Accordingly, the precision of the duty cycle of the output signal can be improved. The level shifter having such a switching mechanism can be applied to high-speed applications.

According to one embodiment, a level shifter is provided. The level shifter converts a first input signal and a second input signal to an output signal. The first input signal and the second input signal have opposite phases. The level shifter includes a cross-coupled circuit, a protection circuit, and a pull-down module. The cross-coupled circuit includes a first pull-up transistor and a second pull-up transistor. The first pull-up transistor and the second pull-up transistor are electrically connected to a first supply voltage terminal having a first supply voltage. The second pull-up transistor selectively conducts the first supply voltage to the output signal in response to the first input signal. The protection circuit includes a first protection transistor and a second protection transistor. The first protection transistor and the second protection transistor are respectively electrically connected to the first pull-up transistor and the second pull-up transistor. The pull-down module includes a first pull-down circuit, a second pull-down circuit, a first switching circuit, and a second switching circuit. The first pull-down circuit is electrically connected to the first protection transistor and a ground terminal having a ground voltage.

The first pull-down circuit receives the first input signal. The second pull-down circuit is electrically connected to the second protection transistor and the ground terminal. The second pull-down circuit receives the second input signal. The second pull-down circuit selectively conducts the output signal to the ground voltage in response to the second input signal. The first switching circuit is electrically connected to the first pull-down circuit. The first pull-down circuit and the first switching circuit are alternatively switched on. The second switching circuit is electrically connected to the second pull-down circuit. The second pull-down circuit and the second switching circuit are alternatively switched on, and the first switching circuit and the second switching circuit are alternatively switched on.

According to another embodiment, an electronic device is provided. The electronic device includes the level shifter and a digital circuit. The digital circuit is electrically connected to the level shifter. The digital circuit receives the output signal from the level shifter.

### BRIEF DESCRIPTION OF THE DRAWINGS

FIG. 1 is a block diagram illustrating components in the level shifter according to an embodiment of the present disclosure.

FIGS. 2A and 2B are schematic diagrams illustrating the operations of an exemplary circuit design corresponding to the level shifter in FIG. 1.

FIG. 3 is a schematic diagram illustrating components in the level shifter according to another embodiment of the present disclosure.

FIGS. 4A and 4B are schematic diagrams illustrating the operations of the level shifter in FIG. 3.

FIG. 5 is a waveform diagram illustrating signals corresponding to the level shifter in FIGS. 2A and 2B.

FIG. 6 is a waveform diagram illustrating signals corresponding to the level shifter in FIGS. 4A and 4B.

FIGS. 7A, 7B, and 7C are schematic diagrams illustrating the switching circuits that can be implemented with different types of transistors.

FIG. 8 is a schematic diagram summarizing the switching circuits in

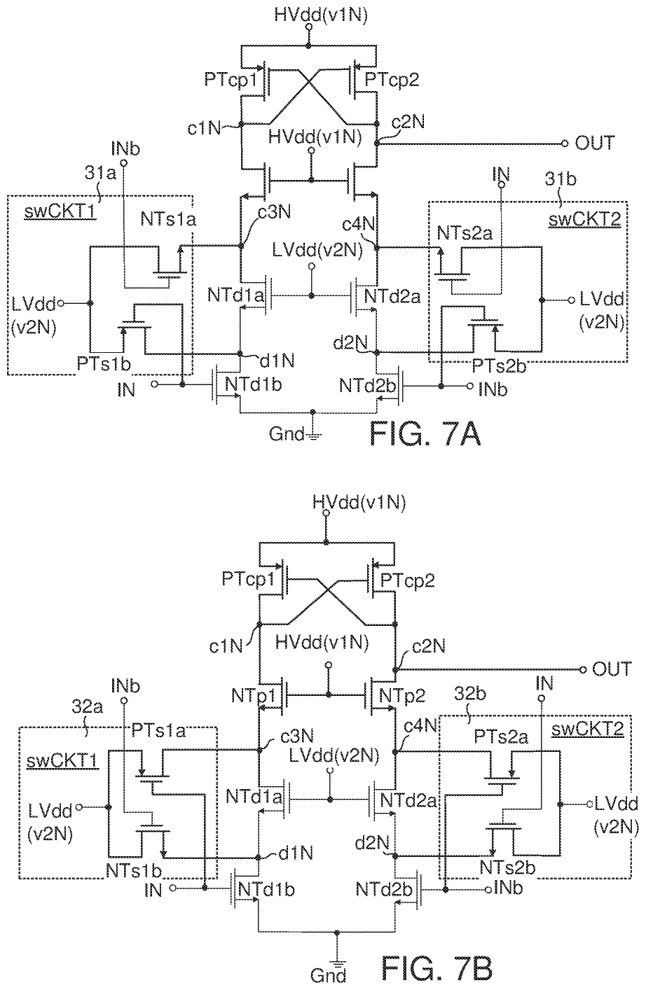

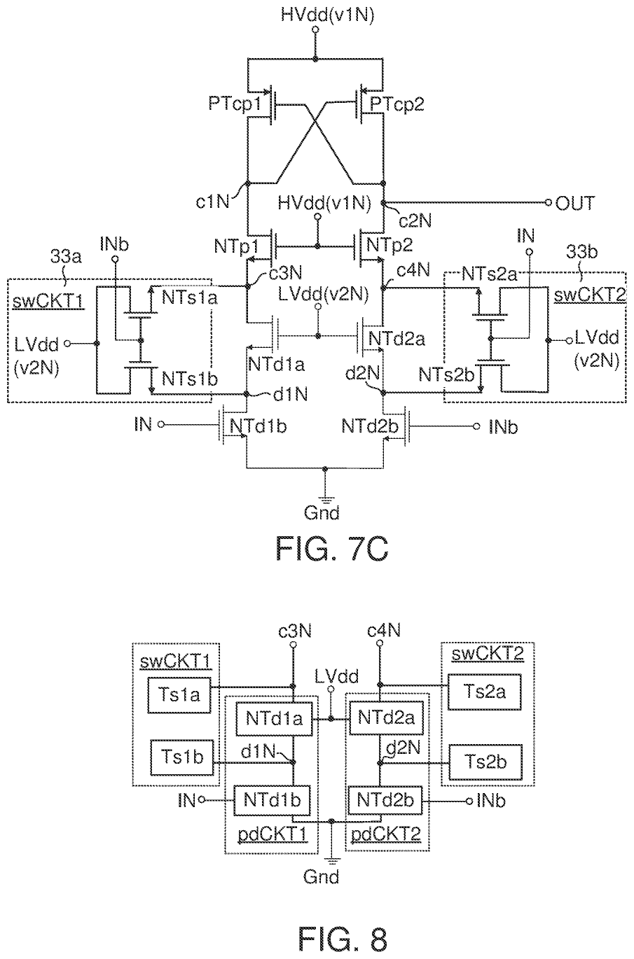

FIGS. 7A, 7B, and 7C.

FIGS. 9A, 9B, and 9C are schematic diagrams illustrating alternative implementations of the pull-down module.

FIG. 10 is a schematic diagram illustrating that the level shifter is enabled by a power-down signal.

In the following detailed description, for purposes of explanation, numerous specific details are set forth in order to provide a thorough understanding of the disclosed embodiments. However, it will be apparent that one or more embodiments may be practiced without these specific details. In other instances, well-known structures and devices are schematically shown in order to simplify the drawing.

### DETAILED DESCRIPTION

As illustrated above, the precision of the output signal OUT of the level shifter affects the subsequent operation in the electronic device. According to the present disclosure, the embodiments of the level shifter provide the output signal OUT with a precise duty cycle to an digital circuit.

In the specification, supply voltages HVdd, LVdd, and a ground voltage Gnd are defined. The terminal corresponding to the supply voltage HVdd is defined as a supply voltage terminal v1N, the terminal corresponding to the supply voltage LVdd is defined as a supply voltage terminal v2N, and the terminal corresponding to the ground voltage Gnd is defined as a ground terminal g1N. The supply voltage HVdd is higher than the supply voltage LVdd (for example, HVdd=0.945V˜1.65V, and LVdd=0.72V˜0.88V), and the supply voltage LVdd is higher than the ground voltage Gnd. Besides, the transistors adopted in the level shifters may be high voltage transistors, low voltage transistor, or their combination.

The level shifter receives an input signal IN and an inverted input signal INb. The input signal IN and the inverted input signal INb have opposite phases and transit between the ground voltage Gnd and the supply voltage LVdd. The output signal OUT transits between the ground voltage Gnd and the supply voltage HVdd. In the drawings, the high voltage transistors are represented in thick solid lines, and the low voltage transistors are represented in thin solid lines.

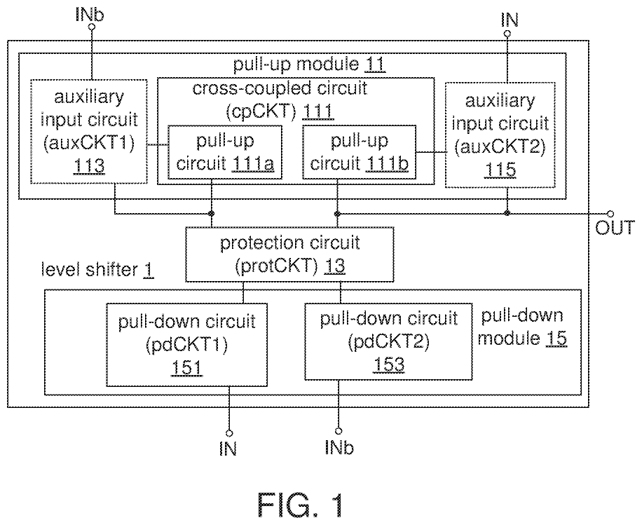

FIG. 1 is a block diagram illustrating components in the level shifter according to an embodiment of the present disclosure. The level shifter 1 includes a pull-up module 11, a protection circuit (protCKT) 13, and a pull-down module 15. The protection circuit (protCKT) 13 is electrically connected to the pull-up module 11 and the pull-down module 15.

The pull-up module 11 includes a cross-coupled circuit (cpCKT) 111 and auxiliary input circuits (auxCKT1) 113, (auxCKT2) 115. The auxiliary input circuits (auxCKT1) 113, (auxCKT2) 115 are optional.

The cross-coupled circuit (cpCKT) 111 includes pull-up circuits 111a, 111b. The pull-up circuit 111a is electrically connected to the auxiliary input circuit (auxCKT1) 113 and the protection circuit (protCKT) 13. The pull-up circuit 111b is electrically connected to the auxiliary input circuit (auxCKT2) 115 and the protection circuit (protCKT) 13. The auxiliary input circuit (auxCKT1) 113 receives the inverted input signal INb, and the auxiliary input circuit (auxCKT2) 115 receives the input signal IN.

The pull-down module 15 includes pull-down circuits (pdCKT1) 151, (pdCKT2) 153. The pull-down circuit (pdCKT1) 151 receives the input signal IN, and the pull-down circuit (pdCKT2) 153 receives the inverted input signal INb.

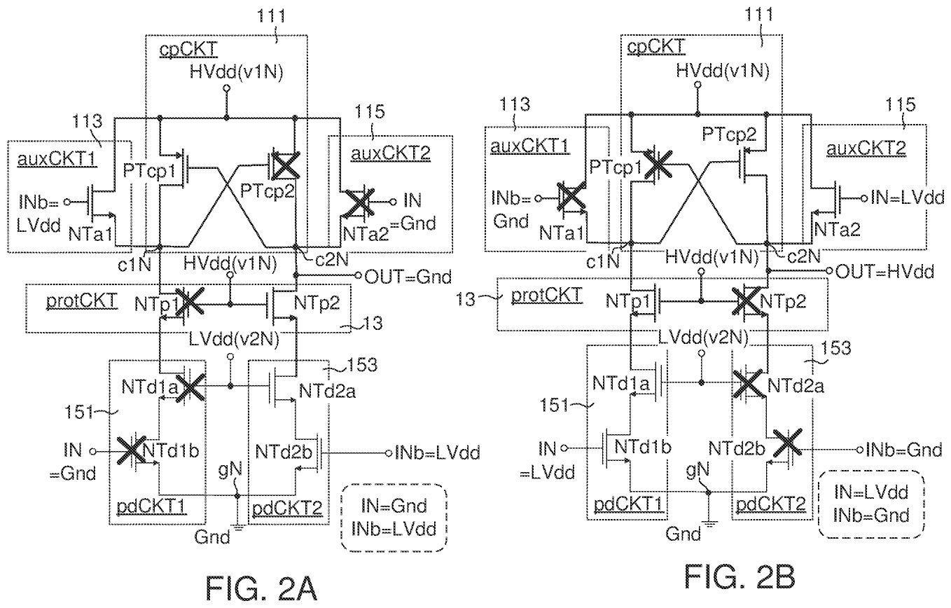

FIGS. 2A and 2B are schematic diagrams illustrating the operations of an exemplary design corresponding to the level shifter in FIG. 1. Please refer to FIGS. 1, 2A, and 2B together. The components in the level shifter 1 are illustrated in top-down order.

The components in the cross-coupled circuit (cpCKT) 111 are introduced. The pull-up circuit 111a is a pull-up transistor PTcp1, and the pull-up circuit 111b is a pull-up transistor PTcp2. The pull-up transistors PTcp1, PTcp2 are PMOS transistors. The source terminals of pull-up transistors PTcp1, PTcp2 are electrically connected to the supply voltage terminal v1N. The drain terminal of pull-up transistor PTcp1 and the gate terminal of pull-up transistor PTcp2 are electrically connected to a conduction terminal c1N. The drain terminal of pull-up transistor PTcp2 and the gate terminal of pull-up transistor PTcp1 are electrically connected to a conduction terminal c2N. The signal at the conduction terminal c2N is defined as an output signal OUT of the level shifter 1.

The auxiliary input circuit (auxCKT1) 113 can be, for example, an auxiliary input transistor NTa1, and the auxiliary input circuit (auxCKT2) 115 can be, for example, an auxiliary input transistor NTa2. The auxiliary input transistors NTa1, NTa2 are NMOS transistors. The drain terminals of auxiliary input transistors NTa1, NTa2 are electrically connected to the supply voltage terminal v1N. The gate terminal of auxiliary input transistor NTa1 receives the inverted input signal INb, and the gate terminal of auxiliary input transistor NTa2 receives the input signal IN. The source terminal of the auxiliary input transistor NTa1 is electrically connected to the conduction terminal c1N, and the source terminal of the auxiliary input transistor NTa2 is electrically connected to the conduction terminal c2N.

The protection circuit (protCKT) 13 includes protection transistors NTp1, NTp2. The protection transistors are NMOS transistors. The gate terminals of protection transistors NTp1, NTp2 are electrically connected to the supply voltage terminal v1N. The drain terminal of protection transistor NTp1 is electrically connected to the conduction terminal c1N, and the drain terminal of protection transistor NTp2 is electrically connected to the conduction terminal c2N.

The pull-down circuit (pdCKT1) 151 includes pull-down transistors NTd1a, NTd1b, and the pull-down circuit (pdCKT2) 153 includes pull-down transistors NTd2a, NTd2b. The pull-down transistors NTd1a, NTd1b, NTd2a, NTd2b are NMOS transistors. The gate terminals of pull-down transistors NTd1a, NTd2a are electrically connected to the supply voltage terminal v2N. The source terminals of pull-down transistors NTd1b, NTd2b are electrically connected to the ground terminal gN.

The drain terminal of pull-down transistor NTd1a is electrically connected to the source terminal of the protection transistor NTp1. The source terminal of pull-down transistor NTd1a is electrically connected to the drain terminal of pull-down transistor NTd1b. The gate terminal of pull-down transistor NTd1b receives the input signal IN.

The drain terminal of pull-down transistor NTd2a is electrically connected to the source terminal of protection transistor NTp2. The source terminal of pull-down transistor NTd2a is electrically connected to the drain terminal of the pull-down transistor NTd2b. The gate terminal of pull-down transistor NTd2b receives the inverted input signal INb.

In FIG. 2A, the input signal IN is set to the ground voltage Gnd, and the inverted input signal INb is set to the supply voltage LVdd. That is, IN=Gnd and INb=LVdd. In FIG. 2B, the input signal IN is set to the supply voltage LVdd, and the inverted input signal INb is set to the ground voltage Gnd. That is, IN=LVdd and INb=Gnd. In response to changes of the input signal IN and the inverted input signal INb, the transistors in the level shifter 1 dynamically change their switching statuses. For the sake of illustration, the switching statuses of the transistors in the level shifter 1 are summarized in Table 1, and the transistors in the level shifter 1 being switched off are labeled with cross signs in FIGS. 2A and 2B.

TABLE 1

| | | FIG. 2A | FIG. 2B |
|---|---|---|---|
| input signal IN | | Gnd | LVdd |
| inverted input signal INb | | LVdd | Gnd |
| cross-coupled | pull-up transistor | ON | OFF |
| circuit (cpCKT) | PTcp1 | | |
| | pull-up transistor | OFF | ON |
| | PTcp2 | | |
| auxiliary input | auxiliary input | ON | OFF |
| circuit (auxCKT1) | transistor NTa1 | | |
| auxiliary input | auxiliary input | OFF | ON |
| circuit (auxCKT2) | transistor NTa2 | | |
| protection circuit | protection | OFF | ON |
| (protCKT) | transistor NTp1 | | |
| | protection | ON | OFF |
| | transistor NTp2 | | |
| pull-down circuit | pull-down | OFF | ON |
| (pdCKT1) | transistor NTd1a | | |
| | pull-down | OFF | ON |
| | transistor NTd1b | | |
| pull-down circuit | pull-down | ON | OFF |
| (pdCKT2) | transistor NTd2a | | |
| | pull-down | ON | OFF |
| | transistor NTd2b | | |

In FIG. 2A, the pull-down transistor NTd1b is switched off as the input signal IN received at its gate terminal is set to the ground voltage Gnd, and the pull-down transistor NTd2b is switched on as the inverted input signal INb received at its gate terminal is set to the supply voltage LVdd. Thus, the pull-down transistor NTd1a and the protection transistor NTp1 are switched off, although their gate terminals respectively receive the supply voltages LVdd, HVdd. Meanwhile, the pull-down transistors NTd2a, NTd2b and the protection transistor NTp1 are switched on.

As the protection transistor NTp1 is switched off, the signal at the conduction terminal c1N is determined by the pull-up transistor PTcp1 and the auxiliary input transistor NTa1.

As the protection transistor NTp2 and the pull-down transistors NTd2a, NTd2b are all switched on, the conduction terminal c2N is conducted to the ground voltage Gnd through the protection transistor NTp2 and pull-down transistors NTd2a, NTd2b. Thus, the output signal OUT (the signal at the conduction terminal c2N) is set to the ground voltage Gnd.

In the cross-coupled circuit (cpCKT) 111, the pull-up transistor PTcp1 is switched on as its gate terminal receives the ground voltage Gnd (c2N=Gnd). In the auxiliary input circuit (auxCKT1) 113, the auxiliary input transistor NTa1 is switched on as its gate terminal receives the supply voltage LVdd (INb=LVdd).

Since the pull-up transistor PTcp1 and the auxiliary input transistor NTa1 are both switched on, two parallel conduction paths are formed between the supply voltage terminal v1N and the conduction terminal c1N. Thus, the conduction terminal c1N is set to the supply voltage HVdd.

In the cross-coupled circuit (cpCKT) 111, the pull-up transistor PTcp2 is switched off because its gate terminal receives the supply voltage HVdd (c1N=HVdd). In the auxiliary input circuit (auxCKT2) 115, the auxiliary input transistor NTa2 is switched off as its gate terminal receives the ground voltage Gnd (IN=Gnd). Since the pull-up transistor PTcp2 and the auxiliary input transistor NTa2 are both switched off, they do not involve the voltage level of the conduction terminal c2N.

In FIG. 2A, the auxiliary input transistor NTa1 and the pull-up transistor PTcp1 are simultaneously switched on, and the auxiliary input transistor NTa1 and the pull-up transistor PTcp1 both conduct the supply voltage HVdd to the conduction terminal c1N. Moreover, the auxiliary input transistor NTa2 and the pull-up transistor PTcp2 are simultaneously switched off. Therefore, an auxiliary input transistor and its adjacent pull-up transistor switch in a synchronized manner.

The conduction of the auxiliary input transistor NTa1 accelerates the rising speed of the conduction terminal c1N. Even if there is no auxiliary input transistor NTa1, the conduction terminal c1N can still rise to the supply voltage HVdd via the pull-up transistor PTcp1. Therefore, the use of the auxiliary input transistor NTa1 is optional.

The operations of the components and the signals in FIG. 2B are symmetric to those in FIG. 2A. Therefore, the detailed descriptions about FIG. 2B are omitted. The conduction terminal c1N is set to the ground voltage Gnd because the protection transistor NTp1 and the pull-down transistors NTd1a, NTd1b are switched on. The conduction terminal c2N is set to the supply voltage HVdd because the pull-up transistor PTcp2 and the auxiliary input transistor NTa2 are switched on.

In FIGS. 2A and 2B, the pull-up transistors PTcp1, PTcp2, the auxiliary input transistors NTa1, NTa2, and protection transistors NTp1, NTp2 are high voltage transistors, and the pull-down transistors NTd1a, NTd1b, NTd2a, NTd2b are low voltage transistors. As the protection transistors NTp1, NTp2 are high voltage transistors, the low voltage transistors in the pull-down circuits (pdCKT1) 151, (pdCKT2) 153 can be protected.

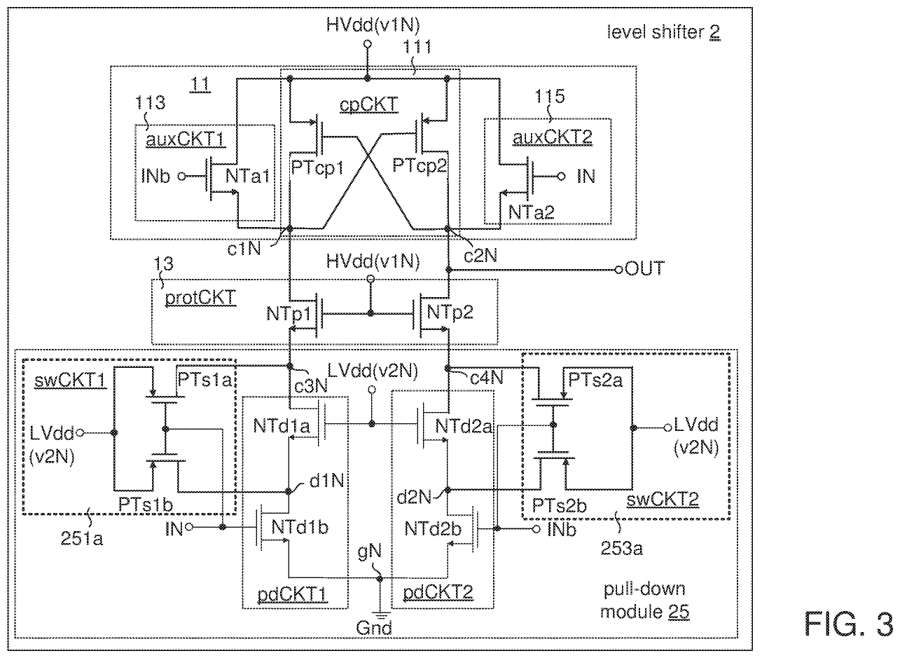

FIG. 3 is a schematic diagram illustrating components in the level shifter according to another embodiment of the present disclosure. Please compare FIG. 3 with FIGS. 2A and 2B. The circuit designs of the pull-up module 11 and the protection circuit 13 in FIGS. 2A, 2B, and 3 are similar. However, the circuit designs of the pull-down modules 15, 25 are different.

Compared with FIGS. 2A and 2B, the pull-down module 25 in FIG. 3 further includes switching circuits (swCKT1) 251a, (swCKT2) 253a, in addition to the pull-down transistors NTd1a, NTd1b, NTd2a, NTd2b. The switching circuit (swCKT1) 251a includes switching transistors PTs1a, PTs1b, and the switching circuit (swCKT2) 253a includes switching transistors PTs2a, PTs2b. The switching transistors PTs1a, PTs1b, PTs2a, PTs2b are PMOS transistors.

In the switching circuit (swCKT1) 251a, the source terminals of switching transistors PTs1a, PTs1b are electrically connected to the supply voltage terminal v2N. The gate terminals of switching transistors PTs1a, PTs1b receive the input signal IN. The drain terminals of switching transistor PTs1a, PTs1b are respectively electrically connected to the conduction terminal c3N and a pull-down terminal d1N.

When the switching transistor PTs1a is switched on, the supply voltage LVdd is conducted to the conduction terminal c3N. Similarly, when the switching transistor PTs1b is switched on, the supply voltage LVdd is conducted to the pull-down terminal d1N. On the other hand, the conduction terminal c3N is disconnected to the supply voltage LVdd when the switching transistor PTs1a is switched off, and the pull-down terminal d1N is disconnected to the supply voltage LVdd when the switching transistor PTs1b is switched off.

Please note that the gate terminals of switching transistors PTs1a, PTs1b, and the gate terminal of pull-down transistor NTd1 b all receive the input signal IN. However, the switching transistors PTs1a, PTs1b are PMOS transistors, and the pull-down transistor NTd1b is an NMOS transistor. This implies that switching statuses of switching transistors PTs1a, PTs1b, and the switching status of pull-down transistor NTd1b are opposite. That is, when the switching transistors PTs1a, PTs1b are switched on, the pull-down transistor NTd1b is switched off, and vice versa.

In the switching circuit (swCKT2) 253a, the source terminals of the switching transistors PTs2a, PTs2b are electrically connected to the supply voltage terminal v2N. The gate terminals of the switching transistors PTs2a, PTs2b receive the inverted input signal INb. The drain terminals of the switching transistor PTs2a, PTs2b are respectively electrically connected to the conduction terminal c4N and a pull-down terminal d2N.

When the switching transistor PTs2a is switched on, the supply voltage LVdd is conducted to the conduction terminal c4N. Similarly, when the switching transistor PTs2b is switched on, the supply voltage LVdd is conducted to the pull-down terminal d2N. On the other hand, the conduction terminal c4N is disconnected to the supply voltage LVdd when the switching transistor PTs2a is switched off, and the pull-down terminal d2N is disconnected to the supply voltage LVdd when the switching transistor PTs2b is switched off.

Please note that the gate terminals of the switching transistors PTs2a, PTs2b, and the gate terminal of pull-down transistor NTd2b all receive the inverted input signal INb. Moreover, the switching transistors PTs2a, PTs2b are PMOS transistors, and the pull-down transistor NTd2b is an NMOS transistor. This implies that switching statuses of the switching transistors PTs2a, PTs2b and the pull-down transistor NTd2b are opposite. That is, when the switching transistors PTs2a, PTs2b are switched on, the pull-down transistor NTd2b is switched off, and vice versa.

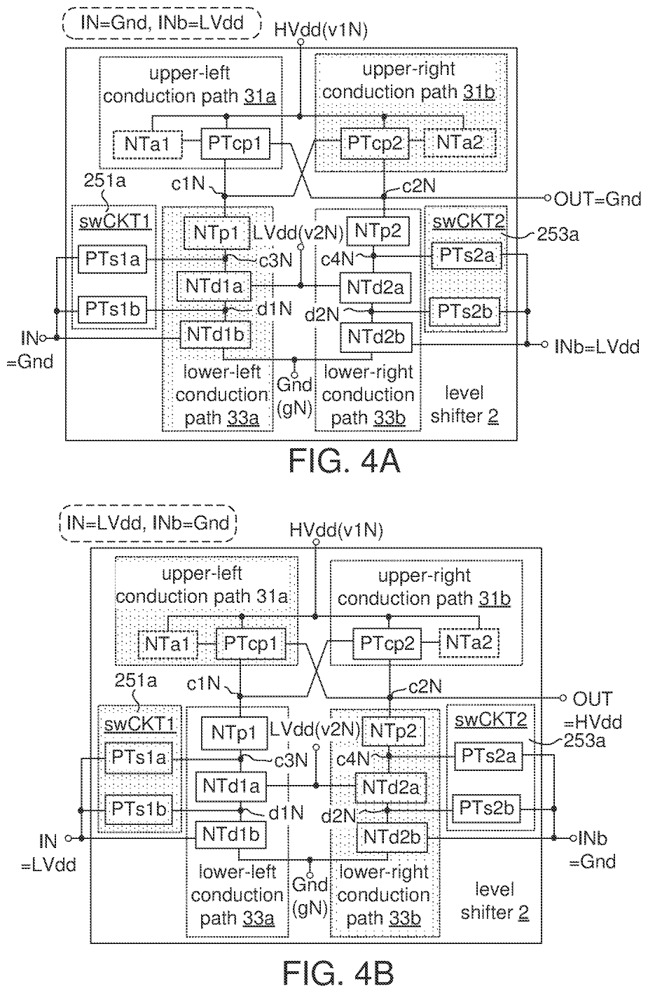

FIGS. 4A and 4B are schematic diagrams illustrating the operations of the level shifter in FIG. 3. The circuit designs of level shifters 1, 2 are similar, except that the level shifter 2 further includes the switching circuits swCKT1, swCKT2. Thus, level shifters 1, 2 operate in a similar manner.

The transistors in level shifter 2 can be classified into different conduction paths, according to their conduction statuses in response to the changes of the input signal IN and the inverted input signal INb. In FIGS. 4A and 4B, the transistors are represented in blocks, and an upper-left conduction path 31a, an upper-right conduction path 31b, a lower-left conduction path 33a, and a lower-right conduction path 33b are defined, based on the positions of the transistors. Moreover, the blocks with screen tone represent the transistors being switched off.

In FIG. 4A, the input signal IN is set to a ground voltage Gnd, and the inverted input signal INb is set to the supply voltage LVdd. That is, IN=Gnd and INb=LVdd. In FIG. 4B, the input signal IN is set to the supply voltage LVdd, and the inverted input signal INb is set to the ground voltage Gnd. That is, IN=LVdd and INb=Gnd. Please refer to FIG. 3, 4A, and 4B together.

The upper-left conduction path 31a includes the auxiliary input transistor NTa1 and the pull-up transistor PTcp1. The upper-right conduction path 31b includes the auxiliary input transistor NTa2 and the pull-up transistor PTcp2. The lower-left conduction path 33a includes protection transistor NTp1 and the pull-down transistors NTd1a, NTd1b. The lower-right conduction path 33b includes the protection transistor NTp2 and the pull-down transistors NTd2a, NTd2b.

Please refer to FIGS. 3 and 4A together. When the input signal IN is set to the ground voltage Gnd and the inverted input signal INb is set to the supply voltage LVdd (IN=Gnd, and INb=LVdd), the transistors (PTcp1, NTa1) in the upper-left conduction path 31a are switched on, the transistors (PTcp2, NTa2) in the upper-right conduction path 31b are switched off, the transistors (NTp1, NTd1a, NTd1b) in the lower-left conduction path 33 are switched off, and the transistors (NTp2, NTd2a, NTd2b) in the lower-right conduction path 33b are switched on. Meanwhile, the switching transistors PTs1a, PTs1b are switched on because their gate terminals receive the ground voltage Gnd (IN=Gnd), and the switching transistors PTs2a, PTs2b are switched off because their gate terminals receive the supply voltage LVdd (INb=LVdd).

Therefore, in FIG. 4A, the switching transistor PTs1a conducts the supply voltage LVdd to the conduction terminal c3N, and the switching transistor PTs1b conducts the supply voltage LVdd to the pull-down terminal d1N. On the other hand, switching transistors PTs2a, PTs2b do not involve the voltage level of the conduction terminal c4N and the pull-down terminal d2N.

As the conduction terminal c3N and the pull-down terminal d1N are both conducted to the supply voltage LVdd, the transistors (NTp1, NTd1a, NTd1b) in the lower-left conduction path 33a are switched off more completely, and the leakage current is prevented from generation. Alternatively speaking, the switching transistors PTs1a, PTs1b can be considered as being utilized to cut off the leakage current along the lower-left conduction path 33a.

Please refer to FIGS. 3 and 4B together. When the input signal IN is set to the supply voltage LVdd and the inverted input signal INb is set to the ground voltage Gnd (IN=LVdd, and INb=Gnd), the transistors (PTcp1, NTa1) in the upper-left conduction path 31a are switched off, the transistors (PTcp2, NTa2) in the upper-right conduction path 31b are switched on, the transistors (NTp1, NTd1a, NTd1b) in the lower-left conduction path 33 are switched on, and the transistors (NTp2, NTd2a, NTd2b) in the lower-right conduction path 33b are switched off. Meanwhile, the switching transistors PTs1a, PTs1b are switched off because their gate terminals receive the supply voltage LVdd (IN=LVdd), and the switching transistors PTs2a, PTs2b are switched on because their gate terminals receive the ground voltage Gnd (INb=Gnd).

Therefore, in FIG. 4B, switching transistors PTs1a, PTs1b do not involve the voltage levels of the conduction terminal c3N and the pull-down terminal d1N. On the other hand, the switching transistor PTs2a conducts the supply voltage LVdd to the conduction terminal c4N, and the switching transistor PTs2b conducts the supply voltage LVdd to the pull-down terminal d2N.

As the conduction terminal c4N and the pull-down terminal d2N are both conducted to the supply voltage LVdd, the protection transistor NTp2 and the pull-down transistors NTd2a, NTd2b are switched off more completely, and the leakage current is prevented from generation. Alternatively speaking, through the conduction of the switching transistors PTs2a, PTs2b, the conduction terminal c4N and the pull-down terminal d2N transit to the supply voltage LVdd immediately after the input signal IN transits from the ground voltage Gnd to the supply voltage LVdd. This feature is further utilized to cut off the leakage current flowing through the lower-right conduction path 33b.

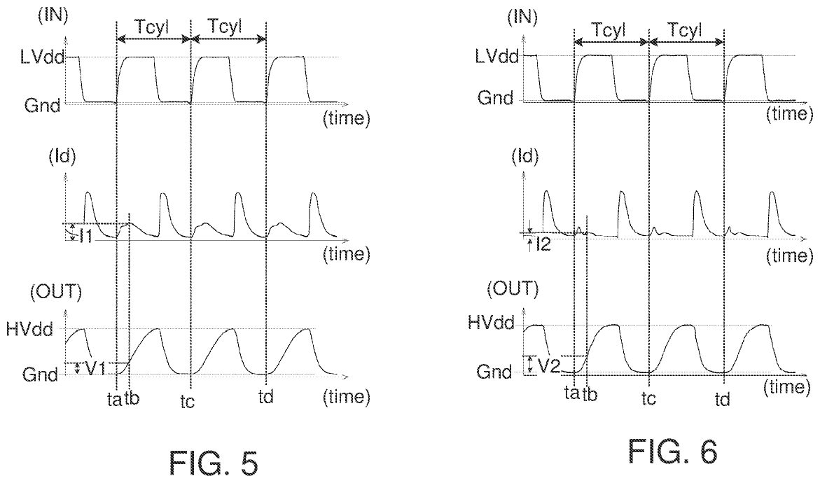

FIG. 5 is a waveform diagram illustrating signals corresponding to the level shifter in FIGS. 2A and 2B. The first waveform represents the input signal IN, the second waveform represents a pull-down current Id flowing through the protection transistor NTp2 and the pull-down transistors NTd2a, NTd2b, and the third waveform represents the output signal OUT.

FIG. 6 is a waveform diagram illustrating signals corresponding to the level shifter in FIG. 3. The first waveform represents the input signal IN, the second waveform represents a pull-down current Id flowing through the lower-right conduction path 33b, and the third waveform represents the output signal OUT.

Please refer to FIGS. 5 and 6 together. The waveforms of the input signal IN are identical. Time points ta, tc, td represent the time points when the input signal IN starts to transit from the ground voltage Gnd to the supply voltage LVdd. The cycle of the input signal IN is represented as Tcyl. The duration between time points ta, tc is equivalent to a cycle of the input signal IN (Tcyl=Tc−Ta), and the duration between the time points tc, td is equivalent to another cycle of the input signal IN (Tcyl=Td−Tc).

In FIGS. 5 and 6, a time point tb is labeled to represent a time point after the rising time point ta. In FIG. 5, the pull-down current Id and the output signal OUT at time point tb are respectively defined as a current value I1 and a voltage value V1. In FIG. 6, the pull-down current Id and the output signal OUT at time point tb are respectively defined as a current value I2 and a voltage value V2.

Compared with the current value I1, the current value I2 is much lower. This implies that when the input signal IN transits from the ground voltage Gnd to the supply voltage LVdd, the pull-down current Id=I2 corresponding to the level shifter 2 in FIGS. 3, 4A, and 4B drops faster than the pull-down current Id=I1 corresponding to the level shifter 1 in FIGS. 1, 2A, and 2B. The switching circuit swCKT2 contributes to that the pull-down current Id=I2 corresponding to the level shifter 2 drops faster than the pull-down current Id=I1 corresponding to the level shifter 1. In short, the adoption of the switching circuit swCKT2 results in the decrement of the leakage current along the lower-right conduction path because the conduction terminal c4N and the pull-down terminal d2N are conducted to the supply voltage LVdd.

The variation of the output signal OUT is related to the pull-down current Id. When the pull-down current Id is greater, the output signal OUT is lower. Therefore, the voltage value V1 is much lower than the voltage value V2 because the current value of the pull-down current Id in FIG. 5 (Id=I1) is greater than the current value of the pull-down current in FIG. 6 (Id=I2). Consequentially, the rising speed of the output signal OUT in FIG. 6 is faster than the rising speed of the output signal OUT in FIG. 5. Alternatively speaking, the speed that the output signal OUT in FIG. 6 reacts to the change of the input signal IN is much faster than the speed of the output signal OUT in FIG. 6. Thus, the duty cycle of the output signal OUT in FIG. 6 is closer to 50% duty cycle than that of the output signal OUT in FIG. 5. A simulation result shows that the duty cycle of the output signal OUT can be improved by about 8% when the switching circuits swCKT1, swCKT2are used.

The above embodiments demonstrate that the output signal OUT could have a more precise duty cycle when the switching circuits swCKT1, swCKT2 are adopted. In practical applications, switching transistors are not limited to the PMOS transistors in FIG.3, but can be replaced with different types of transistors.

FIGS. 7A, 7B, and 7C are schematic diagrams illustrating the switching circuits that can be implemented with different types of transistors. Please note that the level shifters in FIGS. 7A, 7B, 7C might include the auxiliary input circuits (auxCKT1), (auxCKT2) as well, although the auxiliary input circuits (auxCKT1), (auxCKT2) are excluded here.

In FIG. 7A, the switching transistor NTs1a in the switching circuit (swCKT1) 31a and the switching transistor NTs2a in the switching circuit (swCKT2) 31b are NMOS transistors; and the switching transistor PTs1b in the switching circuit (swCKT1) 31a and the switching transistor PTs2b in the switching circuit (swCKT2) 31b are PMOS transistors. The switching transistors NTs1a, PTs2b are controlled by the inverted input signal INb, and the switching transistors NTs2a, PTs1b are controlled by the input signal IN.

In FIG. 7B, the switching transistor Ns1b in the switching circuit (swCKT1) 32a and the switching transistor Ns2b in the switching circuit (swCKT2) 32b are NMOS transistors; and the switching transistor Ps1a in the switching circuit (swCKT1) 32a and the switching transistor PTs2a in the switching circuit (swCKT2) 32b are PMOS transistors. The switching transistors NTs1b, PTs2a are controlled by the inverted input signal INb, and the switching transistors NTs2b, PTs1a are controlled by the input signal IN.

In FIG. 7C, the switching transistors NTs1a, NTs1b in the switching circuit (swCKT1) 33a and the switching transistors NTS2a, NTs2b in the switching circuit (swCKT2) 33b are NMOS transistors. The switching transistors NTs1a, NTs1b are controlled by the inverted input signal INb, and the switching transistors NTs2a, NTs2b are controlled by the input signal IN.

The switching statuses of switching transistors in the switching circuits (swCKT1), (swCKT2) in FIGS. 7A, 7B, and 7C are similar to those in FIGS. 3, 4A, and 4B. Therefore, the detailed descriptions about operations of FIGS. 7A, 7B, and 7C are omitted. Table 2 summarizes the types of transistors and their received signals mentioned in the embodiments.

TABLE 2

| | switching circuit (swCKT1) | | switching circuit (swCKT2) | |
|---|---|---|---|---|
| FIG. 7A | NMOS transistor | INb, IN | NMOS transistor | IN, INb |
| | (Ns1a), | | (Ns2a), | |
| | PMOS transistor | | PMOS transistor | |
| | (Ps1b) | | Ps2b | |
| FIG. 7B | PMOS transistor | IN, INb | PMOS transistor | INb, IN |
| | (Ps1a), | | (Ps2a), | |
| | NMOS transistor | | NMOS transistor | |
| | (Ns1b) | | (Ns2b) | |
| FIG. 7C | NMOS transistors | INb | NMOS transistors | IN |
| | (Ns1a, Ns1b) | | (Ns2a, Ns2b) | |

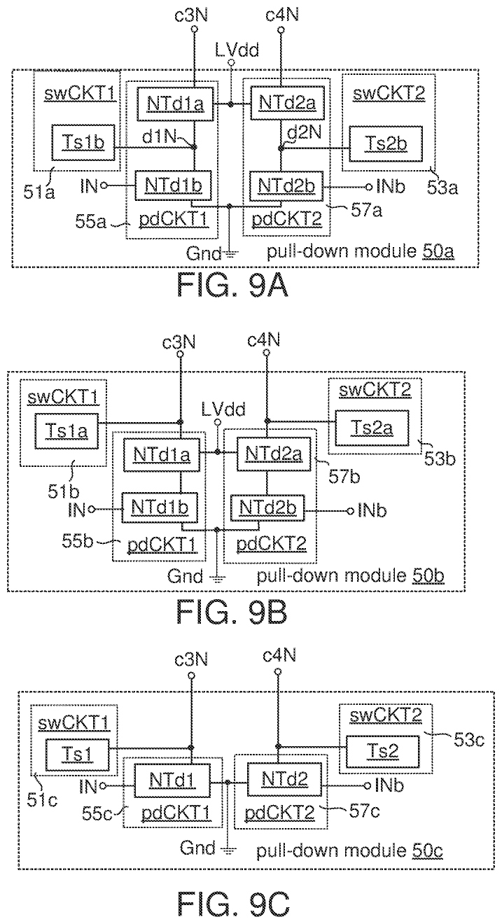

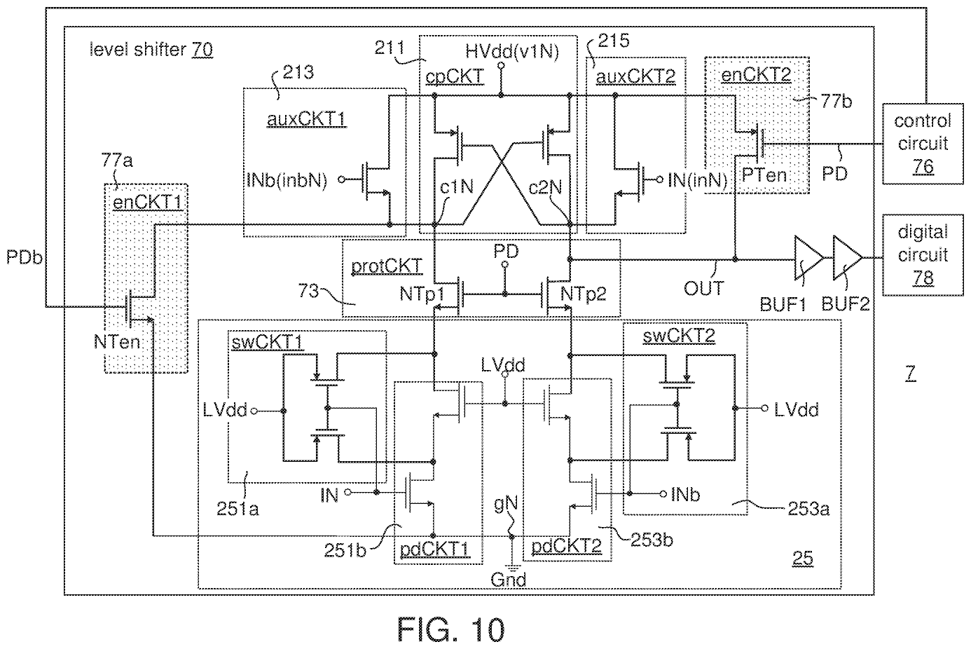

FIG. 8 is a schematic diagram summarizing the switching circuits in FIGS. 7A, 7B, and 7C. In practical applications, the types of switching transistors are not limited to the above examples. Thus, the switching transistors Ts1a, Ts1b, Ts2a, Ts2b can be PMOS transistors, NMOS transistors, or their combinations.

For the switching transistors (Ts1a, Ts1b) in the switching circuit swCKT1, their gate terminals are connected to the input signal IN if they are PMOS transistors or connected to the inverted input signal INb if they are NMOS transistors. For the switching transistors (Ts2a, Ts2b) in the switching circuit swCKT2, their gate terminals are connected to the inverted input signal INb if they are PMOS transistors or connected to the input signal IN if they are NMOS transistors.

FIGS. 7A, 7B, and 7C demonstrate that the types of the transistors (PMOS transistor or NMOS transistor) adopted in the switching circuits swCKT1, swCKT2 are not limited. Moreover, the number of transistors included in the switching circuits swCKT1, swCKT2 is not limited, so as their positions.

FIGS. 9A, 9B, and 9C are schematic diagrams illustrating alternative implementations of the pull-down module. These embodiments demonstrate that the number of transistors included in the pull-down circuits (pdCKT1, pdCKT2) and the switching circuits (swCKT1, swCKT2) are not limited.

In FIG. 9A, the pull-down circuit (pdCKT1) 55a includes pull-down transistors NTd1a, NTd1b, the pull-down circuit (pdCKT2) 57a includes pull-down transistors NTd2a, NTd2b, the switching circuit (swCKT1) 51a includes only switching transistor Ts1b, and the switching circuit (swCKT2) 53a includes only switching transistor Ts2b. The switching transistors Ts1b, Ts2b might be high voltage transistors, low voltage transistors, or their combinations.

When IN=Gnd and INb=LVdd are satisfied, the switching transistor Ts1b and the pull-down transistors NTd2a, NTd2b are switched on, and the switching transistor Ts2b and the pull-down transistors NTd1a, NTd1b are switched off. When IN=Vdd and INb=Gnd are satisfied, the switching transistor Ts1b and the pull-down transistors NTd2a, NTd2b are switched off, and the switching transistor Ts2b and the pull-down transistors NTd1a, NTd1b are switched on. Detailed descriptions about the operations of the pull-down module 50a are omitted.

In FIG. 9B, the pull-down circuit (pdCKT1) 55b includes pull-down transistors NTd1a, NTd1b, the pull-down circuit (pdCKT2) 57b includes pull-down transistors NTd2a, NTd2b, the switching circuit (swCKT1) 51b includes only switching transistor Ts1a, and the switching circuit (swCKT2) 53b includes only switching transistor Ts2a. The switching transistors Ts1a, Ts2a might be high voltage transistors, low voltage transistors, or their combination.

When IN=Gnd and INb=LVdd are satisfied, the switching transistor Ts1a and the pull-down transistors NTd2a, NTd2b are switched on, and the switching transistor Ts2a and the pull-down transistors NTd1a, NTd1b are switched off. When IN=Vdd and INb=Gnd are satisfied, the switching transistor Ts1a and the pull-down transistors NTd2a, NTd2b are switched off, and the switching transistor Ts2a and the pull-down transistors NTd1a, NTd1b are switched on. Detailed descriptions about the operations of the pull-down module 50b are omitted.

In FIG. 9C, the pull-down circuit (pdCKT1) 55c includes only pull-down transistor NTd1, the pull-down circuit (pdCKT2) 57c includes only pull-down transistor NTd2, the switching circuit (swCKT1) 51c includes only switching transistor Ts1, and the switching circuit (swCKT2) 53c include only switching transistor Ts2. The switching transistors Ts1, Ts2 might be high voltage transistors, low voltage transistors, or their combinations.

When IN=Gnd and INb=LVdd are satisfied, the switching transistor Ts1 and the pull-down transistor NTd2 are switched on, and the switching transistor Ts2 and the pull-down transistor NTd1 are switched off. When IN=Vdd and INb=Gnd are satisfied, the switching transistor Ts1 and the pull-down transistor NTd2 are switched off, and the switching transistor Ts2 and the pull-down transistor NTd1 are switched on. Detailed descriptions about the operations of the pull-down module 50c are omitted.

In FIGS. 9A, 9B, and 9C, the switching transistors Ts1a, Ts1b, Ts2a, Ts2b, Ts1, Ts2 may represent PMOS transistor, NMOS transistor, or their combinations. The switching transistors Ts1b, Ts1a, Ts1 can by any types of transistors as long as the switching transistors Ts1b, Ts1a, Ts1 in the switching circuit swCKT1 meet the criteria that they are switched off when the pull-down transistors NTd1a, NTd1b, NTd1 are switched on and vice versa, are not limited. Similarly, the switching transistors Ts2b, Ts2a, Ts2 can be any types of transistors as long as the switching transistors Ts2b, Ts2a, Ts2 in the switching circuit swCKT2 meet the criteria that they are switched off when the pull-down transistors NTd2a, NTd2b, NTd2 are switched on and vice versa.

FIG. 10 is a schematic diagram illustrating the level shifter is enabled by a power-down signal. The electronic device 7 includes a control circuit 76, a digital circuit 78, and a level shifter 70. The digital circuit 78 can be, for example, an on-chip pre-driver or a driver. The control circuit 76 transmits and utilizes a power-down signal PD and an inverted power-down signal PDb to enable/disable the level shifter 70.

The circuit designs of the pull-up module 211, the protection circuit 73, and the pull-down module 25 in the level shifter 70 in FIG. 10 are similar to those in FIG. 3, except that the gate terminals of the protection transistor NTp1, NTp2 receive the power-down signal PD from the control circuit 76. The origin of the power-down signal PD should not be limited in practical applications. In addition, the level shifter 70 further includes enablement circuits (enCKT1) 77a, (enCKT2) 77b and buffers BUF1, BUF2. The buffers BUF1, BUF2 are connected in serial. The input terminal of buffer BUF1 is electrically connected to the conduction terminal c2N, and the output terminal of the buffer BUF2 is electrically connected to the digital circuit 78.

The enablement circuit (enCKT1) 77a is an enablement transistor NTen, and the enablement circuit (enCKT2) 77b is an enablement transistor PTen. The enablement transistor NTen is an NMOS transistors, and the enablement transistor PTen is a PMOS transistor. The drain terminal and the source terminal of enablement transistor NTen are respectively electrically connected to the conduction terminal c1N and the ground terminal gN. The source terminal and the drain terminal of enablement transistor PTen are respectively electrically connected to the supply voltage terminal v1N and the conduction terminal c2N. The gate terminals of enablement transistors NTen, PTen respectively receive the inverted power-down signal PDb and the power-down signal PD. The changes of the enablement transistors NTen, PTen, and the output signal OUT corresponding to the power-down signal PD and the inverted power-down signal PDb are summarized in Table 3.

TABLE 3

| | level shifter 70 is | level shifter 70 is |
|---|---|---|
| | selected | deselected |
| power-down signal PD | Vdd | Gnd |
| inverted power-down | Gnd | Vdd |
| signal PDb | | |
| enablement transistor | OFF | ON |
| NTen | | |
| enablement transistor | OFF | ON |
| PTen | | |
| output signal OUT | OUT = HVdd when | OUT = HVdd |
| | IN = LVdd, or | |
| | OUT = Gnd when | |
| | IN = Gnd | |

When the control circuit 76 selects the level shifter 70, the control circuit 76 sets the power-down signal PD to the supply voltage HVdd (PD=HVdd) and the inverted power-down signal PDb to the ground voltage Gnd (PDb=Gnd). Then, both the enablement transistors PTen, NTen are switched off. Meanwhile, the drain terminals of protection transistors NTp1, NTp2 receive the supply voltage HVdd via the power-down signal PD (PD=HVdd). Accordingly, the operations of the level shifter 70 are identical to other embodiments described before.

When the control circuit 76 deselects the level shifter 70, the control circuit 78 sets the power-down signal PD to the ground voltage Gnd (PD=Gnd) and the inverted power-down signal PDb to the supply voltage HVdd (PDb=HVdd). Meanwhile, the enablement transistor NTen is switched on, and the conduction terminal c1N is fixed at the ground voltage Gnd because PDb=HVdd is satisfied. The enablement transistor PTen is switched on, and the conduction terminal c2N is fixed at the supply voltage HVdd because PD=Gnd is satisfied. Consequentially, the level shifter 70 does not involve the operations of the digital circuit 78. Furthermore, the protection transistors NTp1, NTp2 are switched off as the power-down signal PD is set to the ground voltage Gnd (PD=Gnd). As the protection transistors NTp1, NTp2 are switched off, the crowbar current phenomenon can be prevented.

The embodiments demonstrate that the rise delay of the output signal OUT has been shortened by cutting off the leakage current path with the switching circuits swCKT1, swCKT2. Consequentially, the level shifters in the present disclosure improve the duty cycle precision of the output signal OUT, and become more suitable for high-speed applications having more critical timing restrictions. The adoption of the switching circuits swCKT1, swCKT2 allows the level shifter to support the high-frequency applications. Moreover, the implementations of the switching circuits swCKT1, swCKT2 are flexible.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A level shifter, configured to convert a first input signal and a second input signal to an output signal, wherein the first input signal and the second input signal have opposite phases, and the level shifter comprises:
a cross-coupled circuit, comprising:
a first pull-up transistor, electrically connected to a first supply voltage terminal having a first supply voltage; and
a second pull-up transistor, electrically connected to the first supply voltage terminal, configured to selectively conduct the first supply voltage to the output signal in response to the first input signal;
a protection circuit, comprising:
a first protection transistor, electrically connected to the first pull-up transistor, wherein a first terminal of the first protection transistor is electronically connected to the first pull-up transistor; and
a second protection transistor, electrically connected to the second pull-up transistor, wherein a first terminal of the second protection terminal is electrically connected to the second pull-up transistor, and a gate terminal of the first protection transistor and a gate terminal of the second protection transistor are directly electrically connected to the first supply voltage terminal; and
a pull-down module, comprising:
a first pull-down circuit, electrically connected to a second terminal of the first protection transistor, a second supply voltage terminal having a second supply voltage, and a ground terminal having a ground voltage, configured to receive the first input signal;
a second pull-down circuit, electrically connected to a second terminal of the second protection transistor, the second supply voltage terminal, and the ground terminal, configured to receive the second input signal, wherein the second pull-down circuit selectively conducts the output signal to the ground voltage in response to the second input signal;
a first switching circuit, electrically connected to the first pull-down circuit, wherein the first pull-down circuit and the first switching circuit are alternatively switched on; and
a second switching circuit, electrically connected to the second pull-down circuit, wherein the second pull-down circuit and the second switching circuit are alternatively switched on, and the first switching circuit and the second switching circuit are alternatively switched on.

2. The level shifter according to claim 1, wherein
when the first input signal is set to the ground voltage and the second input signal is set to the second supply voltage,
the first pull-up transistor, the first switching circuit, the second protection transistor, and the second pull-down circuit are switched on, and
the second pull-up transistor, the second switching circuit, the first protection transistor, and the first pull-down circuit are switched off,
wherein the second supply voltage is lower than the first supply voltage, and the second supply voltage is higher than the ground voltage.

3. The level shifter according to claim 1, wherein
when the first input signal is set to the second supply voltage and the second input signal is set to the ground voltage,
the first pull-up transistor, the first switching circuit, the second protection transistor, and the second pull-down circuit are switched off, and
the second pull-up transistor, the second switching circuit, the first protection transistor, and the first pull-down circuit are switched on,
wherein the second supply voltage is lower than the first supply voltage, and the second supply voltage is higher than the ground voltage.

4. The level shifter according to claim 1, wherein
the first pull-down circuit comprises a first-first pull-down transistor, and
the second pull-down circuit comprises a first-second pull-down transistor,
wherein a gate terminal of the first-first pull-down transistor and a gate terminal of the first-second pull-down transistor are electrically connected to the second supply voltage terminal.

5. The level shifter according to claim 4, wherein
the first switching circuit comprises a first-first switching transistor, and
the second switching circuit comprises a first-second switching transistor.

6. The level shifter according to claim 5, wherein
the first-first switching transistor is electrically connected to the first-first pull-down transistor, and
the first-second switching transistor is electrically connected to the first-second pull-down transistor.

7. The level shifter according to claim 5, wherein the first-first switching transistor and the first-second switching transistor are electrically connected to the second supply voltage terminal,
wherein the second supply voltage is lower than the first supply voltage, and the second supply voltage is higher than the ground voltage.

8. The level shifter according to claim 5, wherein
the first-first switching transistor receives one of the first input signal and the second input signal, and
the first-second switching transistor receives the other of the first input signal and the second input signal.

9. The level shifter according to claim 5, wherein
the first pull-down circuit further comprises a second-first pull-down transistor, and
the second pull-down circuit further comprises a second-second pull-down transistor, wherein a gate terminal of the second-first pull-down transistor receives the first input signal, and a gate terminal of the second-second pull-down transistor receives the second input signal.

10. The level shifter according to claim 9, wherein
the first-first switching transistor is electrically connected to the second-first pull-down transistor, and
the first-second switching transistor is electrically connected to the second-second pull-down transistor.

11. The level shifter according to claim 9, wherein
the first switching circuit further comprises a second-first switching transistor, and the second switching circuit further comprises a second-second switching transistor, wherein
the first-first switching transistor is electrically connected to the first-first pull-down transistor and the second-first pull-down transistor,
the second-first switching transistor is electrically connected to the first protection transistor and the second-first pull-down transistor,
the first-second switching transistor is electrically connected to the first-second pull-down transistor and the second-second pull-down transistor, and
the second-second switching transistor is electrically connected to the second protection transistor and the second-second pull-down transistor.

12. The level shifter according to claim 11, wherein
the second-first switching transistor and the second-second switching transistor are electrically connected to the second supply voltage terminal,
wherein the second supply voltage is lower than the first supply voltage, and the second supply voltage is higher than the ground voltage.

13. The level shifter according to claim 9, wherein the first-first pull-down transistor, the first-second pull-down transistor, the second-first pull-down transistor, and the second-second pull-down transistor are NMOS transistors.

14. The level shifter according to claim 9, wherein the first-first pull-down transistor, the first-second pull-down transistor, the second-first pull-down transistor, and the second-second pull-down transistor are low voltage transistors.

15. The level shifter according to claim 1, further comprising:
a first auxiliary input transistor, electrically connected to the first supply voltage terminal, configured to receive the second input signal; and
a second auxiliary input transistor, electrically connected to the first supply voltage terminal, configured to receive the first input signal, wherein the first auxiliary input transistor and the second auxiliary input transistor are alternatively switched on.

16. The level shifter according to claim 15, wherein the first and the second pull-up transistors are PMOS transistors, and the first and the second protection transistors and the first and second auxiliary input transistors are NMOS transistors.

17. The level shifter according to claim 15, wherein the first and the second pull-up transistors, the first and the second protection transistors, and the first and second auxiliary input transistors are high voltage transistors.

18. The level shifter according to claim 1, further comprising:
at least one enablement circuit, electrically connected to the cross-coupled circuit, the protection circuit, and the pull-down module, configured to be selectively switched on in response to a power-down signal, wherein the level shifter is disabled when the at least one enablement circuit is switched on.

19. An electronic device, comprising:
a level shifter, configured to convert a first input signal and a second input signal to an output signal, wherein the first input signal and the second input signal have opposite phases, and the level shifter comprises:
a cross-coupled circuit, comprising:
a first pull-up transistor, electrically connected to a first supply voltage terminal having a first supply voltage; and
a second pull-up transistor, electrically connected to the first supply voltage terminal, configured to selectively conduct the first supply voltage to the output signal in response to the first input signal;
a protection circuit, comprising:
a first protection transistor, electrically connected to the first pull-up transistor, wherein a first terminal of the first protection transistor is electrically connected to the first pull-up transistor; and
a second protection transistor, electrically connected to the second pull-up transistor, wherein a first terminal of the second protection terminal is electrically connected to the second pull-up transistor, and a gate terminal of the first protection transistor and a gate terminal of the second protection transistor are directly electrically connected to the first supply voltage terminal; and
a pull-down module, comprising:
a first pull-down circuit, electrically connected to a second terminal of the first protection transistor, a second supply voltage terminal having a second supply voltage, and a ground terminal having a ground voltage, configured to receive the first input signal;
a second pull-down circuit, electrically connected to a second terminal of the second protection transistor, the second supply voltage terminal, and the ground terminal, configured to receive the second input signal, wherein the second pull-down circuit selectively conducts the output signal to the ground voltage in response to the second input signal;
a first switching circuit, electrically connected to the first pull-down circuit, wherein the first pull-down circuit and the first switching circuit are alternatively switched on; and
a second switching circuit, electrically connected to the second pull-down circuit, wherein the second pull-down circuit and the second switching circuit are alternatively switched on, and the first switching circuit and the second switching circuit are alternatively switched on; and
a digital circuit, electrically connected to the level shifter, configured to receive the output signal from the level shifter.

20. The electronic device according to claim 19, wherein
when the first input signal is set to the ground voltage and the second input signal is set to the second supply voltage, the first pull-up transistor, the first switching circuit, the second protection transistor, and the second pull-down circuit are switched on, and the second pull-up transistor, the second switching circuit, the first protection transistor, and the first pull-down circuit are switched off; and
when the first input signal is set to the second supply voltage and the second input signal is set to the ground voltage, the first pull-up transistor, the first switching circuit, the second protection transistor, and the second pull-down circuit are switched off, and the second pull-up transistor, the second switching circuit, the first protection transistor, and the first pull-down circuit are switched on,
wherein the second supply voltage is lower than the first supply voltage, and the second supply voltage is higher than the ground voltage.
